(19) United States
(12) Patent Application Publication
(10) Pub. No.: US 2009/0027948 A1
(43) Pub. Date: Jan. 29, 2009

(54) Integrated Circuits, Method of Programming a Cell, Thermal Select Magnetoresistive Element, Memory Module

(76) Inventor: Manfred Ruehrig, Eckental (DE)

Correspondence Address: SLATER & MATSIL, L.L.P., 17950 PRESTON ROAD, SUITE 1000, DALLAS, TX, 75252, US

(21) Appl. No.: 11/782,578

(22) Filed: Jul. 24, 2007

(51) Int. Cl. G11C 11/00

(52) U.S. Cl. 365/158

(57) ABSTRACT

An embodiment of the invention includes an integrated circuit that has a cell. The cell includes a first magnetic layer arrangement having a magnetization which corresponds to a predefined ground state magnetization, a non-magnetic spacer layer coupled to the first layer arrangement, a second magnetic layer arrangement disposed on the opposite side of the non-magnetic spacer layer with regard to the first magnetic layer arrangement, the second magnetic layer arrangement having a magnetization fixation temperature that is lower than the magnetization fixation temperature of the first magnetic layer arrangement, and at least a portion of the second magnetic layer arrangement having a closed magnetic flux structure in its demagnetized state.

### TECHNICAL FIELD

Embodiments of the present invention relate generally to integrated circuits, a method of programming a cell, a thermal select magnetoresistive element, and a memory module.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a block diagram of a thermal select magnetoresistive memory cell arrangement in accordance with an exemplary embodiment of the invention;

FIG. 2 shows the structure of a thermal select memory cell in a cross-sectional view in accordance with one exemplary embodiment of the invention;

FIG. 3 shows a thermal select memory cell in side view in accordance with an exemplary embodiment of the invention;

FIG. 4 shows a top view of a thermal select memory cell in accordance with an exemplary embodiment of the invention;

FIG. 5 shows a block diagram showing the reading of a programming state of a thermal select memory cell in accordance with an exemplary embodiment of the invention;

FIG. 6 shows a flow diagram of a method of programming a thermal select memory cell in accordance with an exemplary embodiment of the invention;

FIG. 7 shows a flow diagram showing another method of programming a thermal select memory cell in accordance with an exemplary embodiment of the invention;

FIG. 8 shows a diagram showing the linear dependence of an ohmic resistance of a magnetic layer of a thermal select memory cell in accordance with an exemplary embodiment of the invention from its magnetic orientation; and

FIGS. 9A and 9B show block diagrams illustrating switching fields of a conventional thermal select memory cell (FIG. 9A) and a thermal select memory cell in accordance with an exemplary embodiment of the invention (FIG. 9B).

### DETAILED DESCRIPTION OF ILLUSTRATIVE EMBODIMENTS

As used herein the terms “connected” and “coupled” are intended to include both direct and indirect connection and coupling, respectively.

In a conventional magnetoresistive random access memory (MRAM) storage concept, the information about the magnetization state of a storage layer cell is stored in the form of a logic “0” and logic “1”, respectively, wherein the respective memory cell is considered to be approximately saturated, in other words, it is considered to be in a single-domain state, and is switched from one logic state (magnetization direction) into another logic state using an external magnetic field (usually by superimposing two external magnetic fields).

In this case, a compromise should be found between an as small as possible switching field (in order to achieve a good switchability) and sufficient thermal stability. This is particularly difficult if small cell dimensions (cell geometries) are required for reasons of scaling, since both parameters are contradictory to one another.

In an embodiment of the invention, memory cells are used which are thermally selectable, as will be explained in more detail below. In this kind of approach, which is also called “thermally activated writing” or “thermally activated programming”, the switching field of the memory cells to be programmed is reduced only for a short time period during the programming process. During the remaining time of the operation of the memory cell array, the switching field is selected to be high enough to be stable with regard to thermal fluctuations. This kind of memory cell, which will also be referred to as a thermal select memory cell in the following, substantially decouples both effects from one another. In a particular case, in which the thermal stability of the memory layer cell is affected by a so-called “exchange-coupled” storage layer and the programming is carried out by heating the system (storage layer and possibly exchange-coupling layer, which is also referred to as an anti-ferromagnet) above the so-called blocking temperature TB, in which the exchange-coupling, which is also denoted as pinning, of the magnetization orientation of the storage layer, disappears or is significantly reduced.

The embodiments of the invention that are described in the following all use thermal select memory cells since in case of programming (that is in case that the temperature is higher than the blocking temperature (T>T_{B})), the switching characteristic of the selected memory cell is usually settable independently from the side condition of the thermal stability.

However, there are still some side conditions which have an impact on the switching of the memory layer above the blocking temperature T_{B}. In accordance with an embodiment, the memory layers cannot become or cannot be designed arbitrarily thin, since the tunnelling magnetoresistance signal (TMR signal) would suffer or the layers would no longer grow continuously, in other words, they would not result in a continuous and homogeneous layer and furthermore, the couplings between the reference layer or the reference system (which might include a plurality of layers that together form the reference system) and the storage layer can be exactly balanced only in a very difficult manner (for example, via stray fields or the unevenness of the surface), which results in production caused variations in the switching field from memory cell to memory cell. The peripheral electronics, in other words, the peripheral circuits controlling the memory cells should in any case provide sufficiently high switching currents in order to compensate such variations in a secure manner. In one particular embodiment of the invention, typical coupling fields are used in the range of a plurality of 3 Oe to 15 Oe, for example, 3 Oe to 10 Oe, for example, 5 Oe, using so-called Néel coupling fields. It should be mentioned that coupling fields which are caused by stray fields are in the same magnitude dependent on the used reference layer. Furthermore, the occurring stray fields are distributed over the memory cell area in a very inhomogeneous way since they are generated by charge carriers at the edge region of the memory cells.

In accordance with an embodiment of the invention, an improvement of the thermal select memory cell approach is provided which is not based on a switching (in other words discrete switching) of the storage layer but on a continuous variation of the magnetization, as will be described in more detail below.

In an embodiment of the invention, a memory cell arrangement is provided, in which the MRAM memory cell is not formed from the common one-domain state for storing a logic “0” or logic “1”, but from a so-called vortex state or flux closed state.

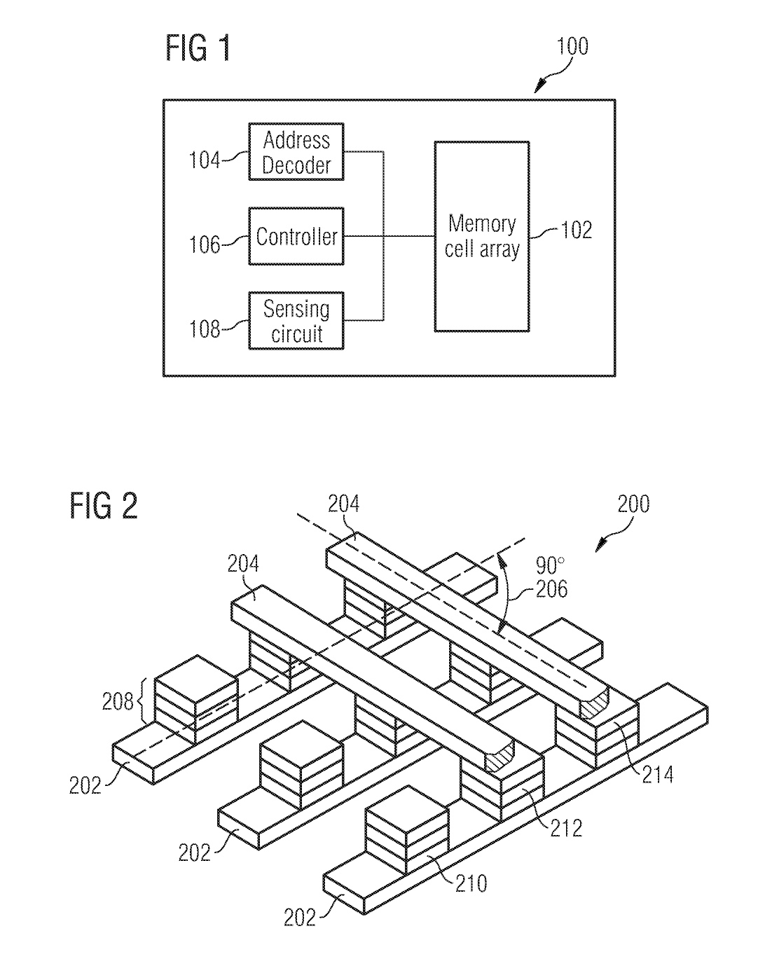

FIG. 1 illustrates a magnetoresistive memory cell arrangement 100 in accordance with an exemplary embodiment of the invention.

The magnetoresistive memory cell arrangement 100 includes, inter alia, a memory cell array 102 which includes a plurality of memory cells, wherein the memory cells may be arranged in rows and columns in a matrix form, and one or a plurality of reference cells which are designed and manufactured in the same way as the memory cells and which provide a reference state in order to determine the memory state of the respectively selected memory cell of the memory cell array, as will be described in more detail below. It should be mentioned that the memory cells in the memory cell array 102 may be arranged in a different way than in a matrix form, for example, in a zig-zag architecture.

Furthermore, the magnetoresistive memory cell arrangement 100 includes an address decoder 104, which receives a logical address of a memory cell to be selected, for example, a memory cell to be programmed, read or erased, and maps the logical address of the memory cell to the actual physical address of the memory cell to be selected within the memory cell array 102. Furthermore, the address decoder 104 provides the select signal to the control lines, to which the memory cell to be selected is connected to such that the desired memory cell within the memory cell array 102 is selected.

Furthermore, a controller 106, for example, a microprocessor, in an alternative embodiment of the invention implemented as hard wired logic, is provided. The controller 106 provides voltage signals in order to provide the required voltages and currents in order to perform the respectively selected operation on the selected memory cell within the memory cell array 102. By way of example, the controller 106 provides a sequence of voltages and currents to a selected memory cell in order, for example, to heat and/or align the magnetization of the selected memory cells.

Furthermore, a sensing circuit 108 is provided, the sensing circuit 108 being, in one embodiment of the invention, formed by one or a plurality of sense amplifiers (for example one or more current amplifier(s) or one or more voltage amplifier(s)) which are used to sense the current flowing through a selected memory cell within the memory cell array 102 and compare it with the current flowing to a selected reference cell, thereby providing a difference current, which may be used for determining the programming state of the memory cell which is selected.

FIG. 2 shows a portion 200 of the memory cell array 102 illustrating the structure of the memory cells within the memory cell array 102 in a perspective view.

The portion 200 shown in FIG. 2 has magnetic stacks arranged in a cross-point array.

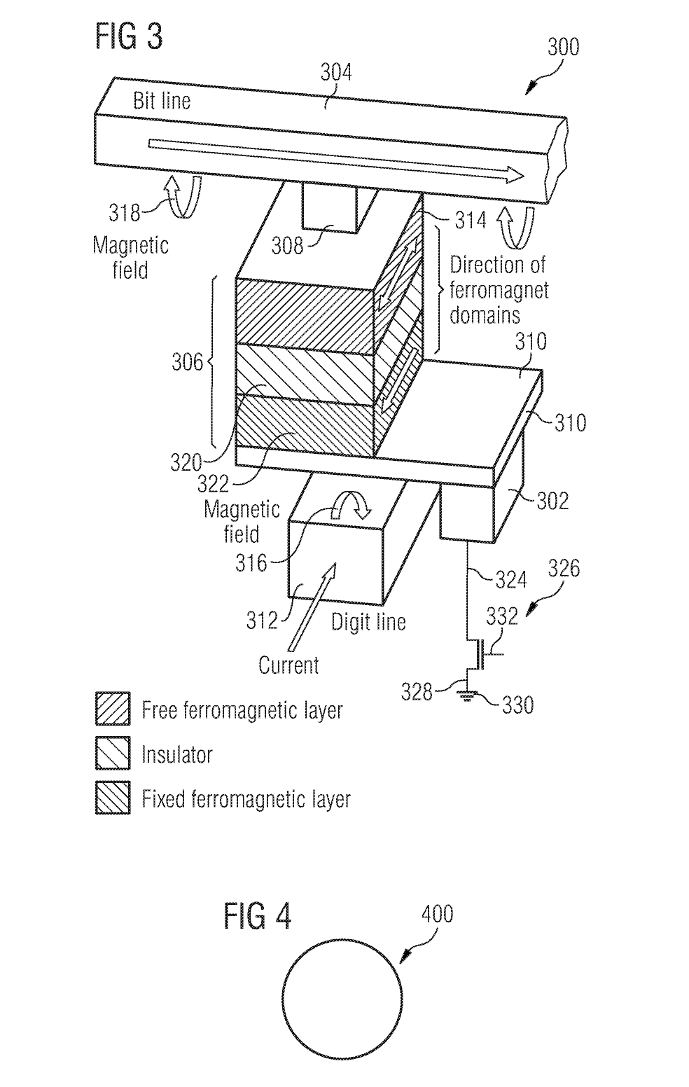

In an alternative embodiment, which is shown, for example, in FIG. 3 and will be outlined below, a select transistor architecture is provided for the memory cells in order to uniquely select each memory cell via a select transistor, as will be described in more detail below.

The portion 200 illustrates that the memory cell array 102 has conductive lines 202 positioned orthogonal to bit lines 204, wherein an angle 206 between the word lines 202 and the bit lines 204 is equal to 90 degrees. A magnetic stack 208 is disposed between and adjacent to word lines 202 and bit lines 204. The magnetic stack 208 includes a first magnetic layer 210, in the following also referred to as hard magnetic layer 210, a tunnel layer 212, also referred to as tunnel junction 212, and a second magnetic layer 214, also referred to as soft magnetic layer 214. A logic state is stored in the alignment of magnetic moments in the magnetic stack 208, as will be described in more detail below, by sending a current through the word lines 202 and bit lines 204.

In an alternative embodiment of the invention, the magnetic stack 208 further includes anti-ferromagnetic subsystems in order to fix the magnetic orientation of the reference layer 210 (also referred to as pinning the magnetic orientation of the reference layer), in other words of the hard magnetic layer 210, and, in an embodiment of the invention, also of the soft magnetic layer 214. In case anti-ferromagnets are provided for pinning the magnetic orientation of the hard magnetic layer 210 as well as for pinning the magnetic orientation of the soft magnetic layer 214, respectively, the anti-ferromagnets have different blocking temperatures, as will be described in more detail below.

The reference layer system can comprise a plurality of layers and can be formed as single magnetic layer or as an artificial anti-ferromagnet. Both embodiments may be exchange-coupled to a natural antiferromagnet.

The structure of the magnetic stack 208 is the same as the structure of the magnetic stack as it is shown in the embodiment of FIG. 3 and which will be described in more detail below in an alternative embodiment of the invention.

The embodiment shown in FIG. 3 differs from the embodiment shown in FIG. 2, for example, in that an additional select transistor and an additional conductor line for providing an additional external magnetic switching field for switching the magnetic orientation of the soft magnetic layer 214 of the magnetic stack 208 is provided.

The memory cell arrangement portion 300 according to the embodiment illustrated in FIG. 3 includes a plurality of word lines 302 and bit lines 304 and a plurality of magnetic stacks 306, only one of which is shown in FIG. 3.

The structure of the magnetic stacks 208 and 306 are identical and will be described in more detail below.

The magnetic stack 306 in accordance with FIG. 3 is coupled to the bit line 304 on its one end via a contact block 308 and to the word line 302 via a metallically conductive coupling plate 310, which is connected to the other end of the magnetic stack 306 on the one hand and to the laterally displaced word line 302. Vertically aligned with the magnetic stack 306, in accordance with an embodiment of the invention, an additional conductor line 312 is provided, also referred to as digit line 312. The digit line 312 provides an additional external magnetic switching field for switching the magnetic orientation of the soft magnetic layer 314 of the magnetic stack 306. The first external magnetic field 316 which is provided by the digit line 312, to be more exact by a current flowing through the digit line 312, is superimposed to a second external magnetic field 318 being generated by a current flowing through the bit line 304. The superimposed two external fields 316 and 318 result in a total magnetic field that is sufficient to change or set the magnetic orientation of the soft magnetic layer 314 into a desired magnetic orientation.

The magnetic stack 306 further includes a tunnel layer 320 and a hard magnetic layer 322. In this embodiment of the invention, the soft magnetic layer 314 is coupled to the bit line 304, and the hard magnetic layer 322 is coupled to the word line 302 via the conductive coupling plate 310. In an alternative embodiment of the invention, however, the magnetic stack 306 can be turned around such that the soft magnetic layer 314 would then be coupled to the word line 302 via the metal plate 310 and the hard magnetic layer 322 would then be coupled to the bit line 304 via the contact block 308.

Furthermore, the word line 302 is connected to a first source/drain terminal 324 of a select transistor 326, a second source/drain terminal 328 of which is connected to a predetermined reference potential, for example, the mass potential 330, in other words, the second the second source/drain terminal is grounded. The gate terminal 332 of the select transistor 326 is connected to a select signal selecting the respective memory cell for being programmed (written) or read.

In the following, the structure of the magnetic stacks 208, 306 in accordance with an exemplary embodiment of the invention will be explained in more detail.

The magnetic stacks 208, 306 may include, as described above, a first magnetic layer 210, 322 including one or more layers of materials such as platinum manganese (PtMn), cobalt iron (CoFe), ruthenium (Ru), and nickel iron (NiFe), for example. The first magnetic layer 210, 322, that is the hard magnetic layer 210, 322 is also referred to herein as a hard layer or reference layer. The first magnetic layer 210, 322 may include a seed layer disposed over the first conductive lines, that is the word lines 202. The seed layer may comprise tantalum nitride (TaN), for example, to prevent corrosion of the word lines 202 during the etching of the magnetic stacks 208, 306.

The magnetic memory stacks 208, 306 also may include a dielectric layer 212, 320, including, for example, aluminium oxide (Al₂O₃), manganese oxide (MgO), titanium oxide, or tantalum oxide. The dielectric layer 212, 320 is deposited on top of the hard magnetic layer 210, 322. The dielectric layer 212, 320 is also referred to herein as a tunnel layer, tunnel barrier or T-barrier. Alternatively, a non-magnetic spacer layer may be used for layers 212 or 320. The material of the non-magnetic spacer layer may be selected from the group of materials including ruthenium, chromium, gold, rhenium, osmium, silver or copper. The non-magnetic spacer layer may comprise a magnetic tunnelling layer disposed between the first magnetic layer arrangement and the second magnetic layer arrangement.

The magnetic stacks 208, 306 also may include a second magnetic layer 214, 314, that is the soft magnetic layer 214, 314 disposed over the dielectric layer 212, 320. The soft magnetic layer 214, 314 is also referred to herein as a soft layer or free layer. In accordance with an embodiment of the invention, the soft magnetic layer 214, 314 includes two or more layers. The second magnetic layer may comprise one or more of cobalt, iron or nickel, and one or more non-ferromagnetic elements such as molybdenum, boron, silicon or phosphorous, or alloys of these materials. The hard magnetic layer 210, 322, the dielectric layer 212, 320 and the soft magnetic layer 214, 314 form the magnetic stacks 208, 306. The magnetic stacks 208, 306 may comprise a substantially rectangular shape, in an alternative embodiment of the invention other shapes such as a circle, square, or ellipse, as an example.

As described in more detail below, in particular the soft magnetic layer 214, 314 and therewith possibly the entire magnetic stack may have a cylindrical shape with a circular cross-sectional shape in top view (see, e.g., top view 400 in FIG. 4).

In an embodiment of the invention, the blocking temperature of the anti-ferromagnet that is coupled and assigned to the soft magnetic layer 214, 314 (in order to pin the magnetic orientation of the soft magnetic layer 214, 314), is lower than the Curie temperature of the soft magnetic layer 214, 314 and the hard magnetic layer 210, 322.

In an alternative embodiment of the invention, the magnetic stack 208, 306 further includes a first anti-ferromagnet system for pinning the magnetic orientation of the soft magnetic layer 214, 314. The first anti-ferromagnet can be disposed on or above the soft magnetic layer 214, 314 and may be formed as a natural anti-ferromagnet. In this case, altering the magnetic orientation of the soft magnetic layer 214, 314 according to embodiments of the invention may be carried out by heating the anti-ferromagnet above its blocking temperature, thereby deactivating the pinning function of the anti-ferromagnet and then changing the magnetic orientation of the soft magnetic layer 214, 314.

Furthermore, the magnetic stack 208, 306 may include a second anti-ferromagnet layer system being provided and connected with the hard magnetic layer 210, 322 for pinning its magnetic orientation. In case that two anti-ferromagnetic layers are provided, the blocking temperature of the first anti-ferromagnetic layer is lower than the blocking temperature of the second anti-ferromagnetic layer.

In an embodiment of the invention, a continuous magnetization process is provided in a magnetic thin film element, which is, for example, formed by the soft magnetic layer or a partial layer within the soft magnetic layer. In an embodiment of the invention, the second magnetic layer 214, 314 has a thickness in the range of about 2 nm to about 10 nm, in a particular embodiment in the range of about 3 nm to about 6 nm.

In one embodiment of the invention, the second magnetic layer 214, 314 has a shape, for example, a substantially circular shape, for example, an exact circular shape, such that a closed magnetic flux structure in a demagnetized state is provided, also referred to herein as a vortex state, which shows a linear relationship between the magnetization and the external field. This linear dependency ranges over a wide field range up to a maximum field Hₛₐₜ, at which a saturation is achieved. This saturation field Hₛₐₜ results from the geometric parameters (for example, diameter D and layer thickness t) of the soft magnetic layer 214, 314 according to the following equation:

Hₛₐₜ=t*Mₛ/D, wherein Mₛ is the magnetization at saturation.

For a memory cell made of a soft magnetic NiFe alloy in the following also called permalloy (Py) (that is Mₛ=1 T) having a layer thickness t of about 5 nm and a diameter D of about 100 nm, the saturation field would amount to about 50 mT (that is 500 Oe).

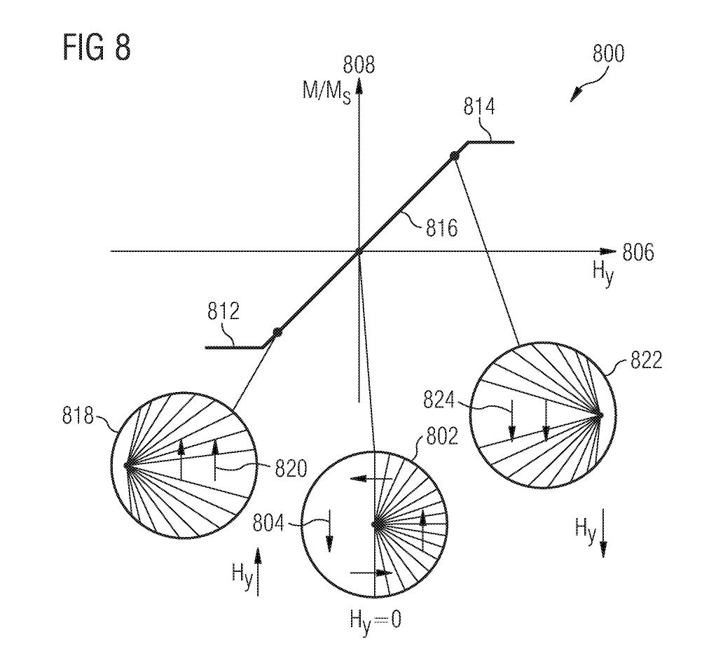

FIG. 8 shows a vortex diagram 800 illustrating this linear relationship.

In particular, the vortex diagram 800 shows for the soft magnetic layer 214, 314 in an embodiment of the invention, the vortex state in the field free state, that is without any external magnetic field H_{y} (in FIG. 8 symbolized by a first soft magnetic layer top view sketch 802, which shows a circular closed flux structure, symbolized by means of arrows 804). The external magnetic field is illustrated in the vortex diagram 800 along a first axis 806. A second axis 808 illustrates the parameter M/Mₛ, that is the magnetization normalized to the saturation magnetization.

With increasing and decreasing external magnetic field H_{y}, the vortex is shifted in a linear manner along a magnetization characteristic 810, which has two saturation regions 812 and 814 and a linear region 816. In both saturation regions 812, 814, in which the external magnetic field is higher in its absolute value than the saturation field Hₛₐₜ, the magnetization of the soft magnetic layer 214, 314 is constant. When decreasing the external magnetic field H_{y}, the magnetization state is linearly shifted from a lower saturated vortex state (symbolized in FIG. 8 in a second soft magnetic layer top view sketch 818), in which the magnetization is in a first direction that corresponds to the direction of the applied saturation field −Hₛₐₜ and which is symbolized by means of second arrows 820. When increasing the external magnetic field H_{y} the magnetization state is shifted in a linear relationship according to the increase of the external magnetic field H_{y} via the vortex state at H_{y}=0 to an upper saturated magnetization state at Hₛₐₜ, which is symbolized in FIG.8 by a third soft magnetic layer top view sketch 822 and the magnetization direction is in this sketch 822 symbolized by third arrows 824. The magnetization direction of the soft magnetic layer 214, 314 is shifted 180 degrees from −Hₛₐₜ to +Hₛₐₜ.

The saturation field is relatively high and in the same magnitude than the switching field for other approaches like the single domain switching which are described above which are expected for those ferrodimensions.

While in those concepts such high switching fields result in that they probably cannot be used for small cells for technological reasons, the above described memory cell embodiment has one effect in that, although in theory, a large switching field of, for example, 500 Oe is necessary to saturate the storage layer (for example, the soft magnetic layer 214, 314), any states between XMR and external magnetic fields can be used to store information in this case (for example, ±19% saturation/XMR hub) due to the linear relationship between magnetization and external field and more or less in an analog manner between XMR and the external magnetic field. In this case, for example, ±15 Oe (another embodiment of the invention ±215 Oe, for example, ±200 Oe, for example, ±250 Oe, for example, ±100 Oe) would be sufficient in order to “switch” from one memory state into another memory state, to be more exact, continuously setting a particular state. Other possibilities may include the adaptation of the soft magnetic layer material (for example, by choosing a material having a low Mₛ) or a smaller soft magnetic layer thickness such that the “switching fields of ±5 Oe can be achieved. These fields can also be generated in those dimensions using integrated conductor lines.

Since TMR signal values from up to 200% to 300% (ΔR/R) can be achieved, the consequence of an embodiment of the invention is that the signal change between a logic “0” and a logic “1” corresponding to the achieved level of the saturation with, for example, only ±10% of the maximum value, can be compensated for.

It will be appreciated by the skilled person that in an embodiment of the invention, the magnetization state of the soft magnetic layer 214, 314, which is set by the external magnetic field H_{y}, is fixed (also referred to as pinned) corresponding to the thermal select approach that has been described above.

In an embodiment of the invention, the above described exchange coupling at a natural anti-ferromagnet, which may be made of iridium manganese (IrMn, FeMn or NiMn), wherein the magnetic stack 208, 306, which in this case may include the hard magnetic layer, the tunnel layer, the soft magnetic layer and the anti-ferromagnet layer system, is heated to a temperature higher than the blocking temperature of the natural anti-ferromagnet during programming of the magnetization state of the soft magnetic layer 214, 314.

FIG. 5 shows in a simplified manner in a diagram 500 a memory cell 502, the state of which should be read, and a reference cell 504, which has the same structure as the memory cell 502 to be read.

By applying corresponding read voltages, which are generated by the controller of the thermal select memory cell arrangement 106, to the memory cell 502 and the reference cell 504, the memory cell 502 provides a memory cell current I_{c} 506 in response to the applied read voltage. The reference cells provide a reference current I_{R} 508, also in response to the applied read voltage.

The memory cell current I_{C} 506 and the reference current I_{R} 508 are both supplied to a difference current sensing circuit 510, which may be formed by a sense amplifier, for example, by a current sense amplifier, in an alternative embodiment of the invention by means of a voltage sense amplifier.

The difference current determining circuit 510 determines (and in an embodiment of the invention also amplifies) the current difference between the cell current I_{C} 506 and the reference current I_{R} 508 (that is I_{C}-I_{R}) and outputs a difference current ΔI 512 to an input of a memory cell state determining unit 514, which may, for example, be implemented by a processor, for example by the controller or by an additional microprocessor, in an alternative embodiment by means of an additional logic circuit. The memory cell state determining unit 514 determines, using, for example, a stored digital table having stored therein respective values of the vortex diagram 800, which is specific for the respective memory cell arrangement and which may be determined in a previous calibration phase, and by, for example, determining, whether the determined difference current ΔI 512 is below or above a predetermined current threshold or lies within a predetermined current range, and thereby determines whether the sensed magnetic cell is in a “high ohmic state” or in a “low ohmic state”. In this way, the binary state of the read magnetic cell is determined.

It should be mentioned that depending on the ability of the sensing circuits, for example of the difference current determining unit 510, an arbitrary number of distinguishable difference current ranges can be provided, thereby enabling storing multiple bits within one memory cell. In an embodiment of the invention, up to 5 to 8 distinguishable memory cell states can be provided with a ΔR/R of about 300% depending on the signal to noise ratio during the signal detection along the linear region 816 of the vortex diagram 800.

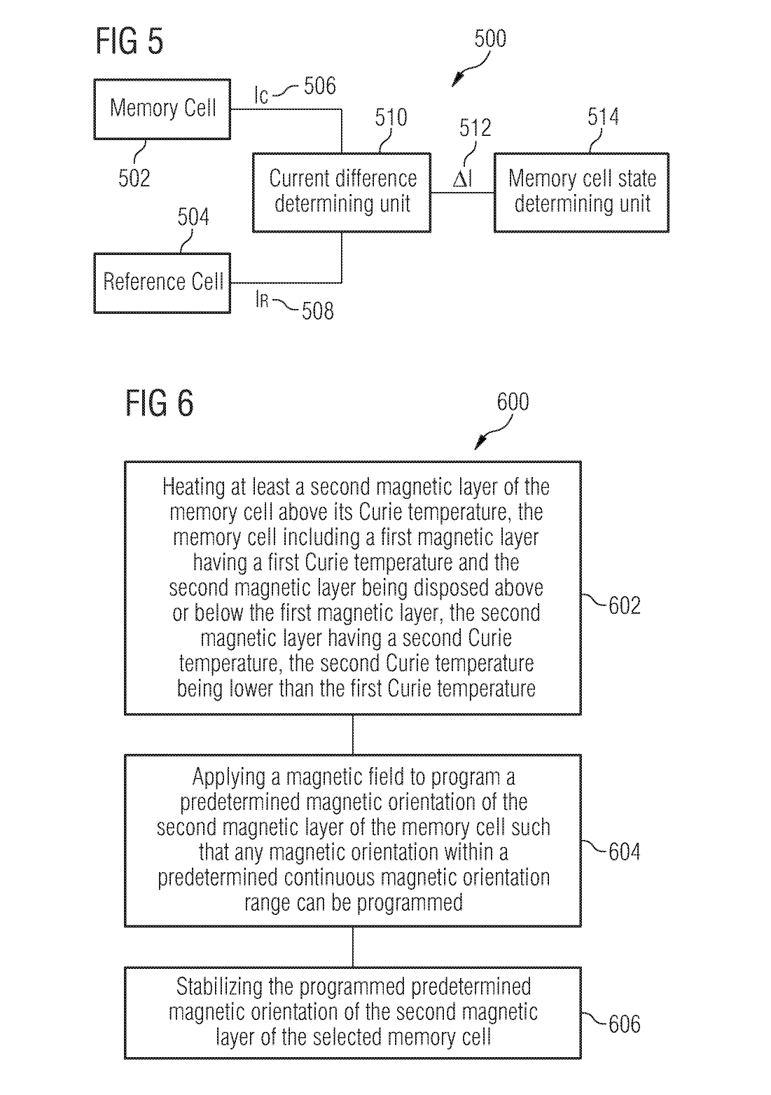

Referring now to FIG. 6, a method of programming a thermal select memory cell is described in accordance with one embodiment of the invention in a flow diagram 600.

In an embodiment of the invention, an anti-ferromagnet is provided and is exchange-coupled to the soft magnetic layer and the natural anti-ferromagnet is heated above its blocking temperature at 602. The heating may be accomplished by applying a suitable current.

At 604, an external magnetic field is applied to program a predetermined magnetic orientation of the second magnetic layer, for example, of the soft magnetic layer 214, 314, of the memory cells such that any magnetic orientation within a predetermined continuous magnetic orientation range can be programmed.

At 606, the programmed predetermined magnetic orientation set in 604 of the second magnetic layer of the selected memory cell is stabilised, for example, by switching of the heating, alternatively by additionally cooling the magnetic stack, in general, the selected memory cell.

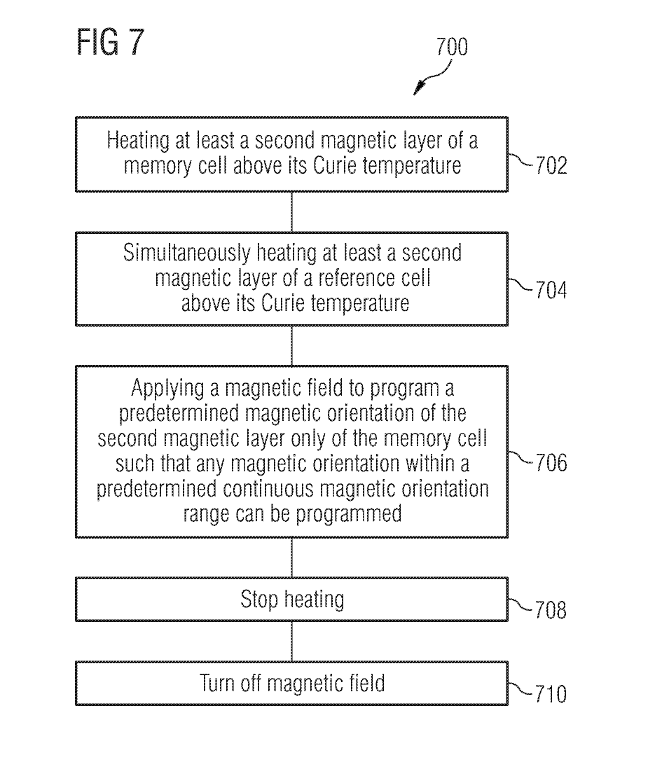

Referring now to FIG. 7, another flow diagram 700 illustrates a method of programming a thermal select magnetic memory cell in accordance with another embodiment of the invention.

At 702, at least the second magnetic layer or the anti-ferromagnetic, the second magnetic layer is coupled with, for example, the entire selected memory cell, is heated above a temperature, for example, the blocking temperature of the provided anti-ferromagnet, such that the fixing of the magnetic orientation of the soft magnetic layer is deactivated.

At 704, simultaneously to heating the selected memory cell, at least the anti-ferrmomagnet, the second magnetic layer is coupled with, for example, the entire magnetic stack of a magnetic reference cell is heated in the same manner, alternatively in a different manner and to a different temperature, but in any case above a temperature, above which the fixing of the magnetic orientation of the soft magnetic layer of the reference cell is deactivated. The heating may be accomplished by applying a suitable current.

At 706, a magnetic field to program a predetermined magnetic orientation of the second magnetic layer only of the memory cell is applied such that any magnetic orientation within the predetermined continuous magnetic orientation range can be programmed. The external magnetic field is not applied to the reference cell in this case so that the reference cell only experiences possible external disturbance fields, which also have an impact on the magnetic orientation of the second magnetic layer of the memory cell to be programmed.

Thereby, a “running” adaptable sensing window is achieved with regard to external disturbance effects.

At 708, the heating is turned off.

Furthermore, at 710, the external magnetic field is also turned off.

It should be mentioned that it is not absolutely necessary to turn off the magnetic field after the heating has turned off, it is also possible to turn the applied magnetic field off before the heating is stopped, but in this case, it should be ensured that the programmed magnetic orientation of the second magnetic layer cannot already relax in a lower energy state while the temperature is still above the blocking temperature, for example, of the anti-ferromagnet.

In an embodiment of the invention, the usage of the linear characteristic of the memory cells in accordance with an embodiment of the invention results in the effect that impacts of disturbance fields (for example, Néel coupling, inhomogenous stray fields, external disturbance fields) can be eliminated in wide ranges, for example, by using a reference cell concept as described above.

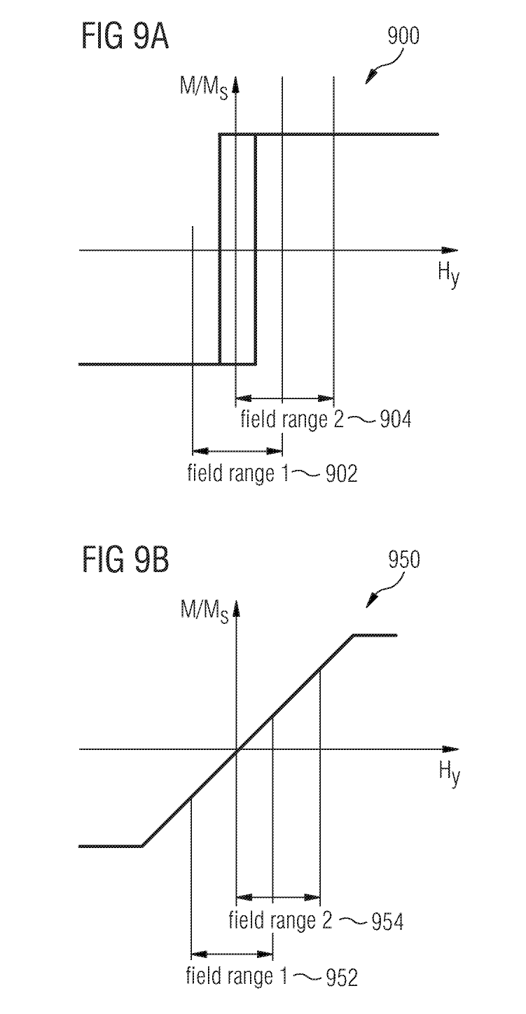

An example is illustrated in FIGS. 9A and 9B. As shown in the diagram 900 which shows a common switching field 902, the maximum signal hub (denoted as field range 1 (reference number 902) in FIG. 9A) without an external disturbance field, can be achieved.

However, already with a relatively low disturbance field (symbolized in FIG. 9A by means of field range 2 (reference number 904), a total failure of the memory can occur, since the storage layer cannot be switched anymore in this case. Thus, the usable field region of an embodiment of the invention, which is illustrated in a second diagram 950 in FIG. 9B, is substantially greater (see field range 1 (reference number 952) without external disturbance field and field range 2 (reference number 954) with an assumed external disturbance field). Therefore, this results in a better process security.

In an embodiment of the invention, for the case of an existing disturbance field, a reference cell having the vortex in its center might be used. If the reference cell is programmed when the disturbance fields, for example, a Néel coupling field or the like exist, the resistance of the reference cell will automatically be set in the middle of the linear field region, that is in the middle of the field range 1 or in the middle of the field range 2, since it still experiences the local disturbance fields even in the “blanket” demagnetized state.

In both cases, a simple comparator circuit as described above would be sufficient to read the memory cell content of the memory cell using the reference cell. A higher resistance than the reference resistance would then be analogous to the common approach a logic “1”, a lower resistance correspondingly a logic “0” or vice versa.

In another embodiment of the invention, even a multi-stage memory, that is, for example, a multi-bit memory is provided by defining a plurality of information states as “bands”, in other words, intervals of different resistance levels.

An effect of another embodiment of the invention is the lower stray field of the memory cells (being dependent from the saturation value that is achieved in the available magnetic field). In this way, the undesired coupling with the adjacent memory cells during programming is reduced.

Furthermore, a continuous “switching” is carried out in a less abrupt manner which leads to a desired narrower distribution of the “switching fields”.

A bi-stable switching of small magnetic elements is usually very much dependent on the perfection of the end regions of the memory cells and thus on the quality of the lithography used during the manufacturing process, since defects in the edge regions can form seed regions for a changing of the magnetization. In an embodiment of the invention, this does not occur in most cases, since the vortex is located approximately in the center of the memory cells and in an ideal situation in the programed cells always have a relative long distance from the edge of the memory cell.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit having a cell, the cell comprising:
a first magnetic layer arrangement having a magnetization which corresponds to a predefined ground state magnetization;
a non-magnetic spacer layer in contact with the first magnetic layer arrangement;
a second magnetic layer arrangement disposed on an opposite side of the non-magnetic spacer layer with regard to the first magnetic layer arrangement, the second magnetic layer arrangement having a magnetization fixation temperature that is lower than the magnetization fixation temperature of the first magnetic layer arrangement; and
at least a portion of the second magnetic layer arrangement having a closed magnetic flux structure in its demagnetized state.

2. The integrated circuit of claim 1, wherein:
the first magnetic layer arrangement comprises a first magnetic layer; and
the second magnetic layer arrangement comprises a second magnetic layer.

3. The integrated circuit of claim 2, wherein the magnetization fixation temperature of the first magnetic layer arrangement is a Curie temperature of the first magnetic layer.

4. The integrated circuit of claim 2, wherein the magnetization fixation temperature of the second magnetic layer arrangement is below the Curie temperature of the second magnetic layer.

5. The integrated circuit of claim 2, wherein the first magnetic layer arrangement further comprises a first anti-ferromagnet magnetically coupled to the first magnetic layer.

6. The integrated circuit of claim 5, wherein the magnetization fixation temperature of the first magnetic layer arrangement is a blocking temperature of the first anti-ferromagnet.

7. The integrated circuit of claim 2, wherein the second magnetic layer arrangement further comprises a second anti-ferromagnet magnetically coupled to the second magnetic layer.

8. The integrated circuit of claim 7, wherein the magnetization fixation temperature of the second magnetic layer arrangement is the blocking temperature of the second anti-ferromagnet.

9. The integrated circuit of claim 2, wherein the second magnetic layer has a closed magnetic flux structure in its demagnetized state.

10. The integrated circuit of claim 1, wherein a predefined ground state of the first magnetic layer is an at least approximately saturated magnetic state.

11. The integrated circuit of claim 2, wherein the second magnetic layer has a shape providing a closed magnetic flux structure in its demagnetized state.

12. The integrated circuit of claim 11, wherein the second magnetic layer has a substantially cylindrical shape.

13. The integrated circuit of claim 12, wherein the second magnetic layer has a substantially cylindrical shape with a substantially circular cross section.

14. The integrated circuit of claim 1, wherein the non-magnetic spacer layer comprises a magnetic tunneling layer disposed between the first magnetic layer arrangement and the second magnetic layer arrangement.

15. The integrated circuit of claim 14, wherein the magnetic tunneling layer is a dielectric layer.

16. The integrated circuit of claim 15, wherein the dielectric layer is made of a material selected from a group of materials consisting of aluminum oxide, magnesium oxide, titanium oxide or tantalum oxide.

17. The integrated circuit of claim 1, wherein the first magnetic layer arrangement comprises a plurality of first magnetic layers being magnetically coupled.

18. The integrated circuit of claim 17, wherein the first magnetic layer arrangement comprises a plurality of non-magnetic spacer layers between respective two first magnetic layers anti-ferromagnetically coupling the respective two first magnetic layers.

19. The integrated circuit of claim 2, wherein the material of the first magnetic layer is selected from a group of materials consisting of iron, cobalt or alloys thereof.

20. The integrated circuit of claim 2, wherein the material of the non-magnetic spacer layer is selected from a group of materials consisting of ruthenium, chromium, gold, rhenium, osmium, silver or copper.

21. The integrated circuit of claim 2, wherein the second magnetic layer is made of a first material selected from a group consisting of cobalt, iron, or nickel, combined with a second non-ferromagnetic material selected from a group consisting of molybdenum, boron, silicon or phosphorous, or combinations thereof.

22. The integrated circuit of claim 1, wherein the cell is a memory cell.

23. The integrated circuit of claim 22, wherein the memory cell is a magnetoresistive memory cell.

24. The integrated circuit of claim 23, wherein the memory cell is a thermal select magnetoresistive memory cell.

25. The integrated circuit of claim 22, wherein the cell is a multi-bit memory cell.

26. An integrated circuit having a cell arrangement, the cell arrangement comprising:
a plurality of cells, each cell comprising:
a first magnetic layer arrangement having a magnetization which corresponds to a predefined ground state magnetization;
a non-magnetic spacer layer coupled to the first magnetic layer arrangement;
a second magnetic layer arrangement disposed on the opposite side of the non-magnetic spacer layer with regard to the first magnetic layer arrangement, the second magnetic layer arrangement having a magnetization fixation temperature that is lower than the magnetization fixation temperature of the first magnetic layer arrangement; and
at least a portion of the second magnetic layer arrangement having a closed magnetic flux structure in its demagnetized state.

27. The integrated circuit of claim 26, wherein the cells are memory cells.

28. The integrated circuit of claim 27, wherein the memory cells are magnetoresistive memory cells.

29. The integrated circuit of claim 28, wherein the memory cells are thermal select magnetoresistive memory cells.

30. The integrated circuit of claim 26, further comprising:
a plurality of select transistors, one select transistor being provided for each cell and selecting the respective cell.

31. The integrated circuit of claim 26, further comprising:
a plurality of conductor lines providing an external magnetic field to at least one memory cell.

32. The integrated circuit of claim 29, further comprising:
a heater heating at least one memory cell of the plurality of memory cells.

33. The integrated circuit of claim 32, further comprising:
a controller controlling programming of a selected memory cell, the programming comprising:
heating at least the first magnetic layer arrangement above its magnetization fixation temperature;
applying a magnetic field to program a predetermined magnetic orientation of the second magnetic layer arrangement of the selected memory cell; and
stabilizing the programmed predetermined magnetic orientation of the second magnetic layer arrangement of the selected memory cell.

34. The integrated circuit of claim 27, further comprising:
at least one reference memory cell providing a reference current in accordance with its programming state.

35. The integrated circuit of claim 26, wherein:
the first magnetic layer arrangement of each cell comprises a first magnetic layer; and
the second magnetic layer arrangement of each cell comprises a second magnetic layer.

36. The integrated circuit of claim 35, wherein the second magnetic layer of each cell has a shape providing a closed magnetic flux structure in its demagnetized state.

37. The integrated circuit of claim 36, wherein the second magnetic layer of each cell has a substantially cylindrical shape.

38. The integrated circuit of claim 37, wherein the second magnetic layer of each memory cell has a substantially cylindrical shape with a substantially circular cross section.

39. The integrated circuit of claim 26, wherein the non-magnetic spacer layer further comprises a magnetic tunneling layer disposed between the first magnetic layer arrangement and the second magnetic layer arrangement.

40. The integrated circuit of claim 39, wherein the magnetic tunneling layer of each cell is a dielectric layer.

41. The integrated circuit of claim 40, wherein the dielectric layer of each cell is made of a material selected from a group of materials consisting of aluminum oxide, magnesium oxide, titanium oxide or tantalum oxide.

42. The integrated circuit of claim 26, wherein the first magnetic layer arrangement of each cell comprises a plurality of first magnetic layers being magnetically coupled.

43. The integrated circuit of claim 42, wherein the first magnetic layer arrangement of each cell comprises a plurality of non-magnetic spacer layers between respective two first magnetic layers anti-ferromagnetically coupling the respective two first magnetic layers.

44. The integrated circuit of claim 35, wherein the material of the first magnetic layer of each cell is selected from a group of materials consisting of iron, cobalt or alloys thereof.

45. The integrated circuit of claim 35, wherein the material of the non-magnetic spacer layer of each cell is selected from a group of materials consisting of ruthenium, chromium, gold, rhenium, osmium, silver or copper.

46. The integrated circuit of claim 26, wherein at least some of the cells are multi-bit memory cells.

47. A method of programming a cell, the cell comprising:
a first magnetic layer arrangement having a magnetization which corresponds to a predefined ground state magnetization;
a non-magnetic spacer layer coupled to the first magnetic layer arrangement;
a second magnetic layer arrangement disposed on an opposite side of the non-magnetic spacer layer with regard to the first magnetic layer arrangement, the second magnetic layer arrangement having a magnetization fixation temperature that is lower than the magnetization fixation temperature of the first magnetic layer arrangement; and
at least a portion of the second magnetic layer arrangement having a closed magnetic flux structure in its demagnetized state;
the method comprising:
heating the second magnetic layer arrangement above its magnetization fixation temperature;
applying a magnetic field to program a predetermined magnetic orientation of the second magnetic layer arrangement such that any magnetic orientation within a predetermined continuous magnetic orientation range can be programmed; and
stabilizing the programmed predetermined magnetic orientation of the second magnetic layer arrangement of the cell.

48. The method of claim 47, wherein the heating the second magnetic layer arrangement above its magnetization fixation temperature comprises applying a heating current to at least the second magnetic layer arrangement.

49. The method of claim 47, wherein the applying the magnetic field to program the predetermined magnetic orientation of the second magnetic layer arrangement comprises programming the predetermined magnetic orientation such that any magnetic orientation within a linear region of a linear resistance/magnetic orientation-characteristic of the second magnetic layer can be programmed.

50. The method of claim 47, further comprising:
programming a reference memory cell into a predetermined reference state.

51. The method of claim 50, wherein programming the reference memory cell into the predetermined reference state is carried out simultaneously with the programming of the cell.

52. A memory module, comprising:
a plurality of integrated circuits, wherein at least one integrated circuit of the plurality of integrated circuits comprises a cell, the cell comprising:
a first magnetic layer arrangement having a magnetization which corresponds to a predefined ground state magnetization;
a non-magnetic spacer layer coupled to the first magnetic layer arrangement;
a second magnetic layer arrangement disposed on an opposite side of the non-magnetic spacer layer with regard to the first magnetic layer arrangement, the second magnetic layer arrangement having a magnetization fixation temperature that is lower than the magnetization fixation temperature of the first magnetic layer arrangement; and
at least a portion of the second magnetic layer arrangement having a closed magnetic flux structure in its demagnetized state.

53. The memory module of claim 52, wherein the memory module is a stackable memory module in which at least some of the integrated circuits are stacked one above the other.
